(19) United States
(12) Patent Application Publication
(10) Pub. No.: US 2011/0217832 A1
(43) Pub. Date: Sep. 8, 2011

(54) METHOD OF FILLING A DEEP TRENCH IN A SUBSTRATE

(76) Inventors: Digvijay Raorane, Chandler, AZ (US); Khalid M. Sirajuddin, San Jose, CA (US); Jon C. Farr, Vallejo, CA (US); Sharma V. Pamarthy, Fremont, CA (US)

(21) Appl. No.: 12/879,924

(22) Filed: Sep. 10, 2010

Related U.S. Application Data
(60) Provisional application No. 61/247,447, filed on Sep. 30, 2009.

(51) Int. Cl. H01L 21/3205; H01L 21/283

(52) U.S. Cl. 438/589; 438/667; 257/E21.295; 257/E21.159

(57) ABSTRACT

Methods of filling deep trenches in substrates are described. A method includes providing a substrate with a deep trench formed therein. The method also includes forming a dielectric layer conformal with the substrate and the deep trench. The method also includes, with the entire portion of the dielectric layer conformal with the deep trench exposed, removing at least a portion, but not all, of the dielectric layer at the top of the deep trench with a relatively low bias plasma etch process.

### CROSS-REFERENCE TO RELATED APPLICATIONS

This application claims the benefit of U.S. Provisional Application No. 61/247,447, filed Sep. 30, 2009, the entire contents of which are hereby incorporated by reference herein.

### BACKGROUND

1) Field

Embodiments of the present invention pertain to the field of semiconductor processing and, in particular, to methods of filling deep trenches in substrates.

2) Description of Related Art

Conventional deposition processes of liner dielectric layers in deep trenches, such as deep silicon via trenches, often exhibit some level of shoulder formation in the deposition profile. During subsequent metal deposition processes, such shoulders in the dielectric liner can inhibit complete filling of a deep trench by conductive layers. Void formation may result.

### SUMMARY

Embodiments of the present invention include methods of filling deep trenches in substrates.

In an embodiment, a method includes providing a substrate with a deep trench formed therein. The method also includes forming a dielectric layer conformal with the substrate and the deep trench. The method also includes, with the entire portion of the dielectric layer conformal with the deep trench exposed, removing at least a portion, but not all, of the dielectric layer at the top of the deep trench with a relatively low bias plasma etch process.

In another embodiment, a method includes providing a substrate with a deep trench formed therein. The method also includes forming a dielectric layer conformal with the substrate and the deep trench. The method also includes, with the entire portion of the dielectric layer conformal with the deep trench exposed, removing all of the dielectric layer at the bottom of the deep trench with a relatively high bias plasma etch process. In accordance with an embodiment of the present invention, such an opening of a bottom oxide is useful in a post through silicon via integration process flow.

### BRIEF DESCRIPTION OF THE DRAWINGS

FIG. 1A illustrates a cross-sectional view representing an operation in a conventional method of filling a deep trench in a substrate.

FIG. 1B illustrates a cross-sectional view representing an operation in a conventional method of filling a deep trench in a substrate.

FIG. 1C illustrates a cross-sectional view representing an operation in a conventional method of filling a deep trench in a substrate.

FIG. 1D illustrates a cross-sectional view representing an operation in a conventional method of filling a deep trench in a substrate.

FIG. 2 is a Flowchart representing operations in a method of filling a deep trench in a substrate, in accordance with an embodiment of the present invention.

FIG. 3A illustrates a cross-sectional view representing an operation in a method of filling a deep trench in a substrate, in accordance with an embodiment of the present invention.

FIG. 3B illustrates a cross-sectional view representing an operation in a method of filling a deep trench in a substrate, in accordance with an embodiment of the present invention.

FIG. 3C illustrates a cross-sectional view representing an operation in a method of filling a deep trench in a substrate, in accordance with an embodiment of the present invention.

FIG. 3D illustrates a cross-sectional view representing an operation in a method of filling a deep trench in a substrate, in accordance with an embodiment of the present invention.

FIG. 3E illustrates a cross-sectional view representing an operation in a method of filling a deep trench in a substrate, in accordance with an embodiment of the present invention.

FIG. 4 is a Flowchart representing operations in a method of filling a deep trench in a substrate, in accordance with an embodiment of the present invention.

FIG. 5A illustrates a cross-sectional view representing an operation in a method of filling a deep trench in a substrate, in accordance with an embodiment of the present invention.

FIG. 5B illustrates a cross-sectional view representing an operation in a method of filling a deep trench in a substrate, in accordance with an embodiment of the present invention.

FIG. 5C illustrates a cross-sectional view representing an operation in a method of filling a deep trench in a substrate, in accordance with an embodiment of the present invention.

FIG. 6A illustrates a cross-sectional view representing an operation in a method of filling a deep trench in a substrate, including a repeated deposition/etch cycle process, in accordance with an embodiment of the present invention.

FIG. 6B illustrates a cross-sectional view representing an operation in a method of filling a deep trench in a substrate, including a repeated deposition/etch cycle process, in accordance with an embodiment of the present invention.

FIG. 6C illustrates a cross-sectional view representing an operation in a method of filling a deep trench in a substrate, including a repeated deposition/etch cycle process, in accordance with an embodiment of the present invention.

### DETAILED DESCRIPTION

Methods of filling deep trenches in substrates are described. In the following description, numerous specific details are set forth, such as deposition and etching conditions and material regimes, in order to provide a thorough understanding of embodiments of the present invention. It will be apparent to one skilled in the art that embodiments of the present invention may be practiced without these specific details. In other instances, well-known aspects, such as photolithography patterning and development techniques for trench formation, are not described in detail in order to not unnecessarily obscure embodiments of the present invention. Furthermore, it is to be understood that the various embodiments shown in the Figures are illustrative representations and are not necessarily drawn to scale.

Disclosed herein are methods of filling deep trenches in substrates. In an embodiment, a method includes providing a substrate with a deep trench formed therein. A dielectric layer is then formed conformal with the substrate and the deep trench. Then, with the entire portion of the dielectric layer conformal with the deep trench exposed, at least a portion, but not all, of the dielectric layer at the top of the deep trench is removed with a relatively low bias plasma etch process. In another embodiment, a method includes providing a substrate with a deep trench formed therein. A dielectric layer is then formed conformal with the substrate and the deep trench. Then, with the entire portion of the dielectric layer conformal with the deep trench exposed, all of the dielectric layer at the bottom of the deep trench is removed with a relatively high bias plasma etch process.

The bias of an etch process may be manipulated to locate a primary etch pathway at a particular location on a film. For example, in accordance with an embodiment of the present invention, the shoulders of a dielectric layer in a deep trench are reduced or removed with a relatively low bias etch process to enable improved filling of the deep trench with subsequently deposited layers. In that embodiment, the relatively low bias targets etching of the dielectric layer at the top portion of the deep trench without significantly etching the dielectric layer deeper into the deep trench. In accordance with another embodiment of the present invention, the portion of a dielectric layer at the bottom of a deep trench is removed with a relatively high bias etch process to enable formation of desired features of the deep trench. In that embodiment, the relatively high bias targets etching of the dielectric layer at the bottom portion of the deep trench without significantly etching the dielectric layer in the upper regions of the deep trench. In particular embodiments, a deep trench is a trench having a depth approximately in the range of 1 micron to several hundred microns. In particular embodiments, the terms “filled” or “filling” without further clarification can mean “partially filled” or “partially filling,” “mostly filled” or “mostly filling,” essentially filled” or essentially filling,” or “completely filled” or “completely filling.”

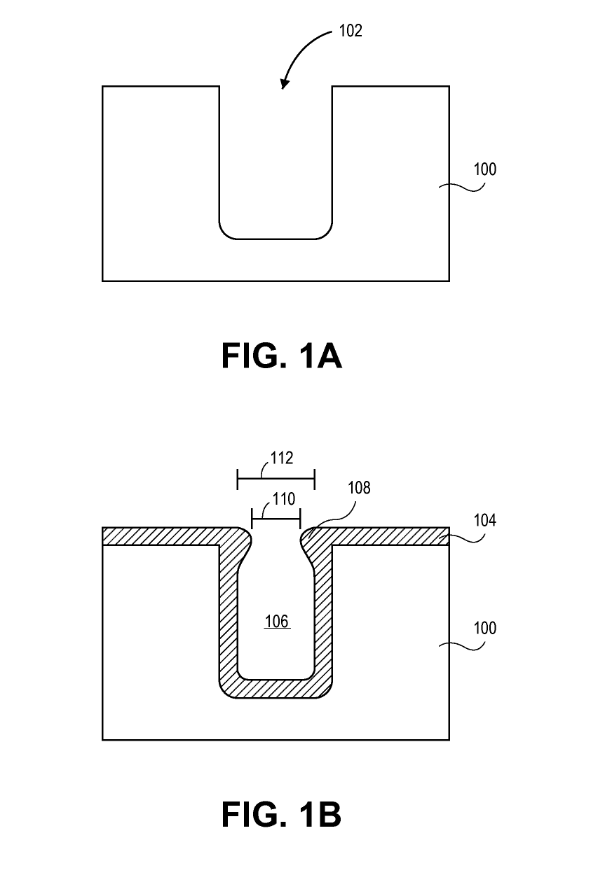

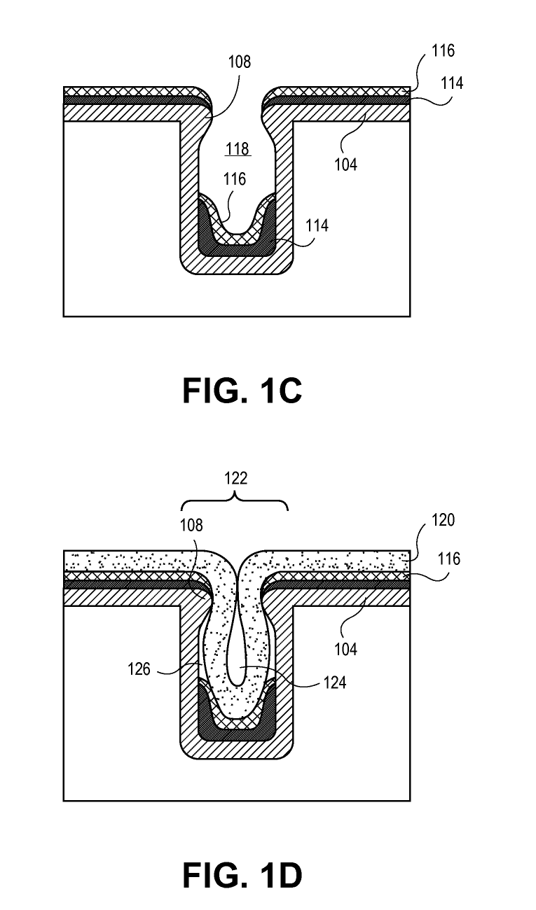

A deep trench etch may be filled using conventional deposition processes. As an example, FIGS. 1A-1D illustrate cross-sectional views representing operations in a conventional method of filling a deep trench in a substrate.

Referring to FIG. 1A, a substrate 100 has a deep trench 102 formed therein. Referring to FIG. 1B, a dielectric layer 104 is formed conformal with substrate 100 and trench 102 to form partially filled trench 106. One feature of the above approach, which may not be desirable, is that dielectric layer 104 may have shoulders 108 that extend over the thickness of the portion of dielectric layer 104 that line the sidewalls of trench 102, as depicted in FIG. 1B. The spacing 110 between the shoulders 108 is less than the width 112 of partially filled trench 106, e.g., less than the width between the sidewalls of dielectric layer 104 lower down in trench 102. The shoulders 108 may result from characteristics inherent in the deposition of dielectric layer 104.

Referring to FIG. 1C, a barrier layer 114 and a seed layer 116 are formed on dielectric layer 104 and in partially filled trench 106 to form partially filled trench 118. However, resulting from the presence of shoulders 108 in dielectric layer 104, one or both of barrier layer 114 and seed layer 116 are discontinuous due to interference with the deposition process by the shoulders 108. Furthermore, the sidewall coverage of partially filled trench 118 may be incomplete, as depicted in FIG. 1C.

Referring to FIG. 1D, a metal layer 120 is formed on seed layer 116 and in partially filled trench 118 to form mostly filled trench 122. However, resulting again from the presence of shoulders 108 in dielectric layer 104, metal layer 120 may be pinched off to form a void 124 due to restriction of access to the entire volume of partially filled trench 118 by the shoulders 108. Furthermore, the sidewall coverage of mostly filled trench 122 may be incomplete to form sidewall voids 126, as depicted in FIG. 1D. Such an arrangement of layers may be unsatisfactory for semiconductor related processes and devices.

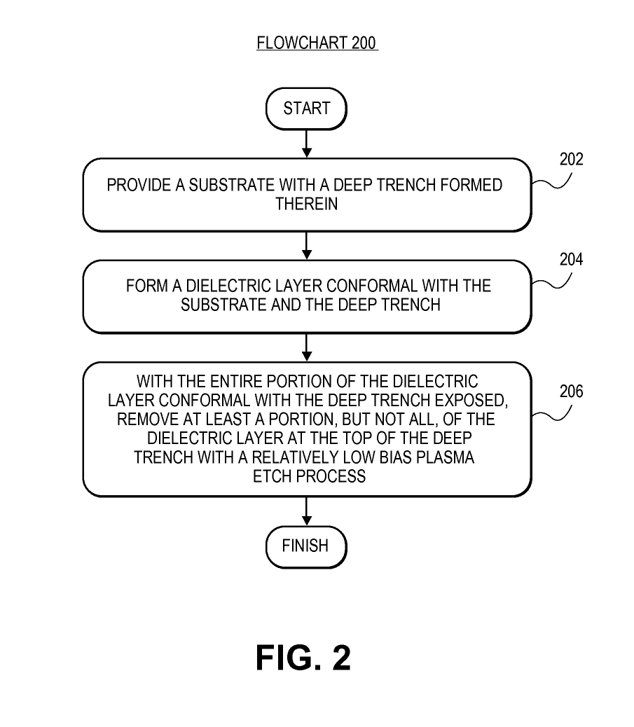

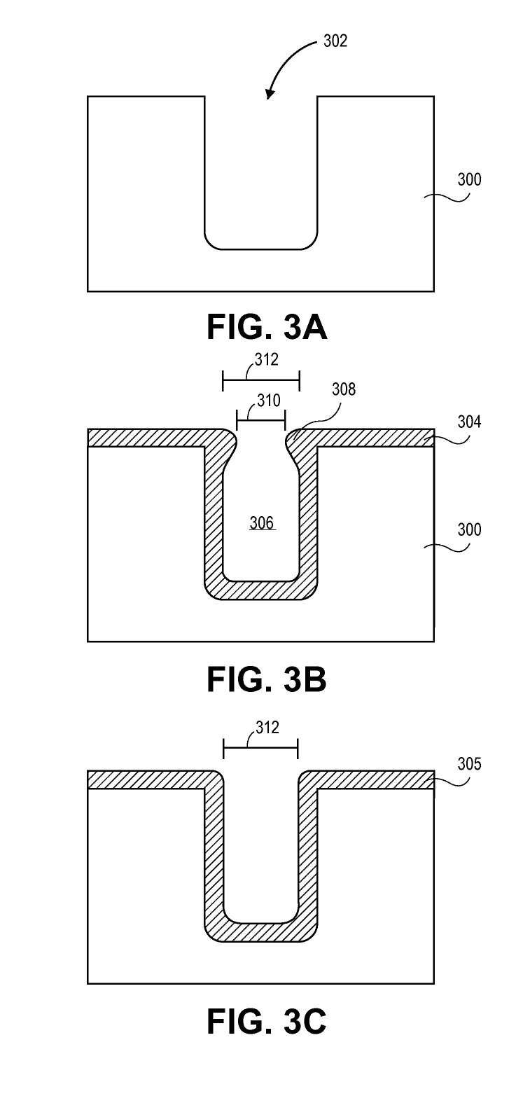

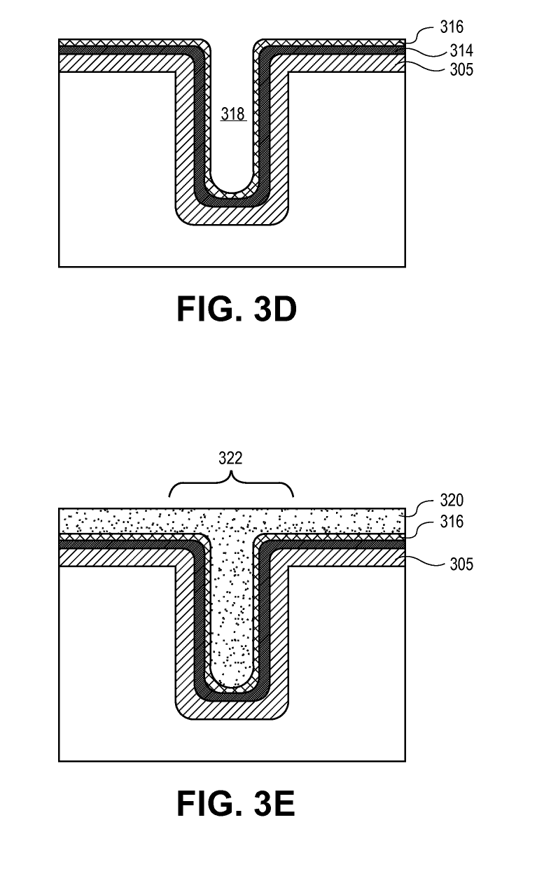

In an aspect of the present invention, the shoulders of a dielectric layer in a deep trench are reduced or removed with a relatively low bias etch process to enable improved filling of the deep trench with subsequently deposited layers. For example, FIG. 2 is a Flowchart 200 representing operations in a method of filling a deep trench in a substrate, in accordance with an embodiment of the present invention. FIGS. 3A-3E illustrate cross-sectional views representing operations in a method of filling a deep trench in a substrate, in accordance with an embodiment of the present invention.

Referring to operation 202 of Flowchart 200 and corresponding FIG. 3A, a method of filling a deep trench in a substrate includes providing a substrate 300 with a deep trench 302 formed therein.

Substrate 300 may be composed of a material suitable to withstand a fabrication process and upon which semiconductor processing layers may suitably reside. In accordance with an embodiment of the present invention, substrate 300 is composed of a group IV-based material such as, but not limited to, crystalline silicon, germanium or silicon/germanium. In a specific embodiment, providing substrate 300 includes providing a monocrystalline silicon substrate. In a particular embodiment, the monocrystalline silicon substrate is doped with impurity atoms. In another embodiment, substrate 300 is composed of a III-V material.

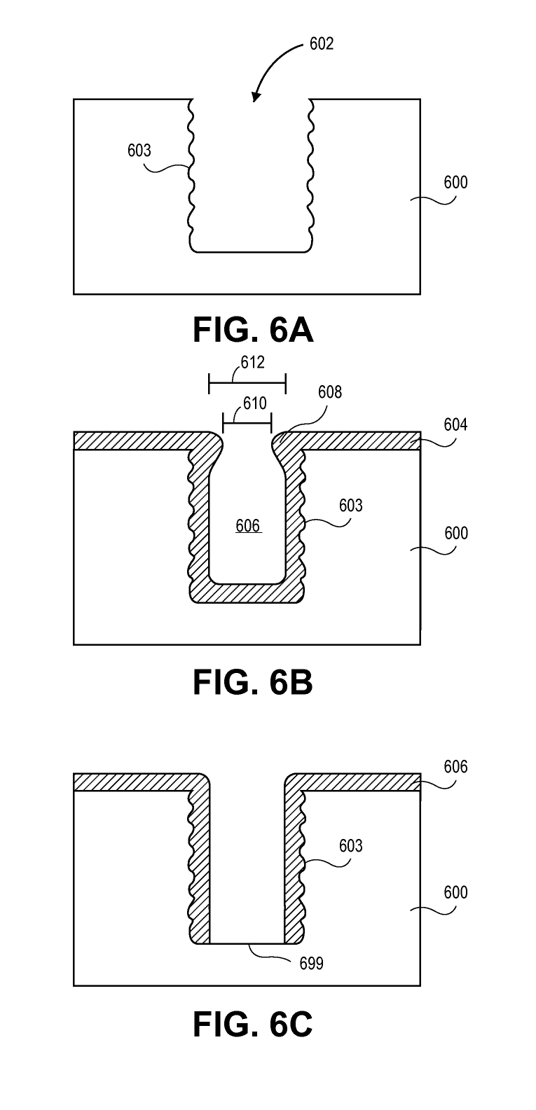

Deep trench 302 may be formed by a process suitable to form a deep trench having approximately the same dimensions, e.g. width, at the top of the trench as the bottom of the trench. In accordance with an embodiment of the present invention, deep trench 302 is formed by first forming a patterning film formed above substrate 300 and then etching substrate 300. The patterning film may be composed of a material suitable for deposition and patterning on a substrate. In an embodiment, the patterning film is composed of a layer of photo-resist and is suitable to withstand a deep substrate etch. The photo-resist layer may be composed of a material suitable for use in a lithographic process. In an embodiment, the photo-resist layer is exposed to a light source and subsequently developed. In one embodiment, the portions of the photo-resist layer to be exposed to the light source will be removed upon developing the photo-resist layer, e.g., the photo-resist layer is composed of a positive photo-resist material. In a specific embodiment, the photo-resist layer is composed of a positive photo-resist material such as, but not limited to, a 248 nm resist, a 193 nm resist, a 157 nm resist, an extreme ultra-violet (EUV) resist and a phenolic resin matrix with a diazonaphthoquinone sensitizer. In another embodiment, the portions of the photo-resist layer to be exposed to the light source will be retained upon developing the photo-resist layer, e.g., the photo-resist layer is composed of a negative photo-resist material. In a specific embodiment, the photo-resist layer is composed of a negative photo-resist material such as, but not limited to, poly-cis-isoprene and poly-vinyl-cinnamate. In an embodiment, the patterning film is composed of an I-line or G-line photo-resist material layer. In an embodiment, upon patterning the patterning film, substrate 300 is etched, e.g. by a plasma etch, in the regions of substrate 300 exposed by the pattern of the patterning film. In accordance with an embodiment of the present invention, deep trench 302 has scalloped features, as described in association with FIG. 6A below.

Referring to operation 204 of Flowchart 200 and corresponding FIG. 3B, a method of filling a deep trench in a substrate includes forming a dielectric layer 304 conformal with substrate 300 and deep trench 302 to provide a partially filled trench 306. In accordance with an embodiment of the present invention, forming dielectric layer 304 conformal with substrate 300 and deep trench 302 includes forming a pair of shoulders 308 at the top portion of deep trench 302, as depicted in FIG. 3B. In an embodiment, the spacing 310 between the pair of shoulders 308 is less than the width 312 of partially filled trench 306, e.g., less than the width between the sidewalls of dielectric layer 304 lower down in deep trench 302. In one embodiment, the pair of shoulders 308 results from characteristics inherent in the deposition of dielectric layer 304.

Dielectric layer 304 may be a material layer suitable for use as an insulating layer. In accordance with an embodiment of the present invention, the insulating layer is composed of a material such as, but not limited to, silicon oxide, silicon dioxide, silicon nitride, silicon oxy-nitride or a high-k dielectric layer. In a particular embodiment, forming dielectric layer 304 includes forming a layer consisting essentially of silicon dioxide. In an embodiment, dielectric layer 304 has a thickness approximately in the range of sub-100 nanometer-3 microns.

Referring to operation 206 of Flowchart 200 and corresponding FIG. 3C, a method of filling a deep trench in a substrate includes, with the entire portion of dielectric layer 304 conformal with deep trench 302 exposed, removing at least a portion, but not all, of dielectric layer 304 at the top of deep trench 302 with a relatively low bias plasma etch process to form modified dielectric layer 305. In accordance with an embodiment of the present invention, removing the portion of dielectric layer 304 at the top of deep trench 302 includes removing at least a portion of the pair of shoulders 308, as depicted in FIG. 3C. In one embodiment, removing the portion of the pair of shoulders 308 includes removing the entirety of the pair of shoulders 308, as is also depicted in FIG. 3C. In a particular embodiment, the width 312 of partially filled trench 306 is the same at the bottom of the trench as at the top of the trench.

The low bias etch process may be an etch process suitable to mostly etch, or even entirely etch, dielectric layer 304 at a location near or at the top of deep trench 306 without significantly etching other regions of dielectric layer 304. In accordance with an embodiment of the present invention, removing the portion of dielectric layer 304 with the relatively low bias plasma etch process includes applying a bias approximately in the range of 0-200 Watts. In one embodiment, removing the portion of dielectric layer 304 with the relatively low bias plasma etch process includes applying a bias approximately in the range of 0-100 Watts. In a specific embodiment, removing the portion of dielectric layer 304 with the relatively low bias plasma etch process includes using a gaseous composition such as, but not limited to, helium or argon carrier gas approximately in the range of 0-400 sccm, along with a gas such as, but not limited to, SF₆ gas approximately in the range of 0-500 sccm, C₄F₈ gas approximately in the range of 0-500 sccm, CHF₃ gas approximately in the range of 0-500 sccm, CF₄ gas approximately in the range of 0-500 sccm, or O₂ gas approximately in the range of 0-100 sccm, the gaseous composition having a pressure approximately in the range of 10-200 mTorr, and the gaseous composition having a source power applied thereto approximately in the range of 1000-5000 Watts.

Referring to FIG. 3D, a method of filling a deep trench in a substrate may also include forming a barrier layer 314 and a seed layer 316 on modified dielectric layer 305 and in deep trench 302 to form partially filled trench 318. In accordance with an embodiment of the present invention, both barrier layer 314 and seed layer 316 are continuous due to lack of interference with the deposition processes of these layers, e.g. interference that would otherwise occur in the presence of shoulders 308. Furthermore, in one embodiment, the sidewall coverage of partially filled trench 318 is complete, as depicted in FIG. 3D.

Barrier layer 314 may be composed of a material suitable to inhibit electro-migration within metal interconnects, to prevent oxidation of the metal interconnects, or to provide a surface for nucleation in a damascene process. In accordance with an embodiment of the present invention, barrier layer 314 is composed of a material such as, but not limited to, tantalum, titanium, tantalum nitride, titanium nitride or a combination thereof. In an embodiment, the thickness of barrier layer 314 is approximately in the range of 5-15 nanometers.

Seed layer 316 may be composed of a material suitable to provide a surface for nucleation in a damascene process. In accordance with an embodiment of the present invention, seed layer 316 is composed of a material such as, but not limited to, copper or a copper/aluminum alloy.

Referring to FIG. 3E, a method of filling a deep trench in a substrate may also include forming a metal fill layer 320 on seed layer 316 and in partially filled trench 318 to form essentially or completely filled trench 322. In accordance with an embodiment of the present invention, metal fill layer 320 is not noticeably, or entirely, pinched off to form a void, as depicted in FIG. 3E. In one embodiment, the sidewall coverage of essentially or completely filled trench 322 is complete and no sidewall voids are formed, as is also depicted in FIG. 3E.

Metal fill layer 320 may be composed of a suitable material that can conduct a current from one end of a metal interconnect to another end of the metal interconnect. In accordance with an embodiment of the present invention, metal fill layer 320 is composed of a material such as, but not limited to, copper, silver, aluminum or an alloy thereof.

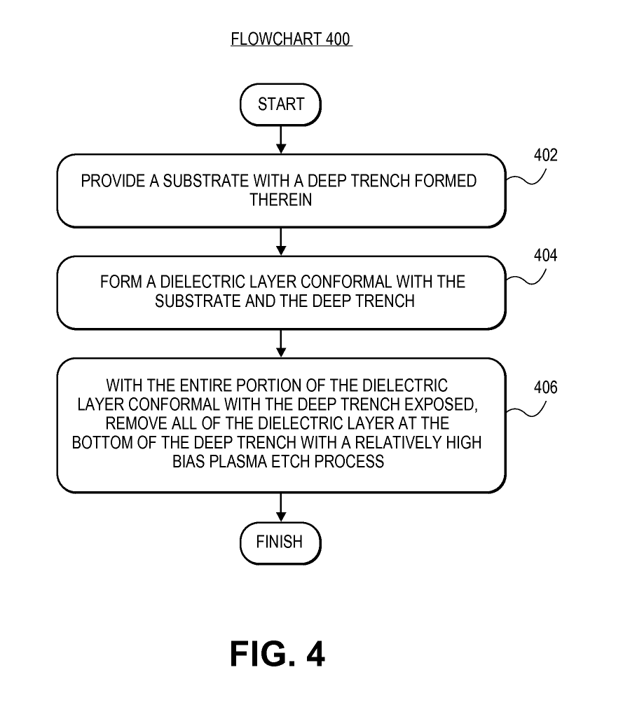

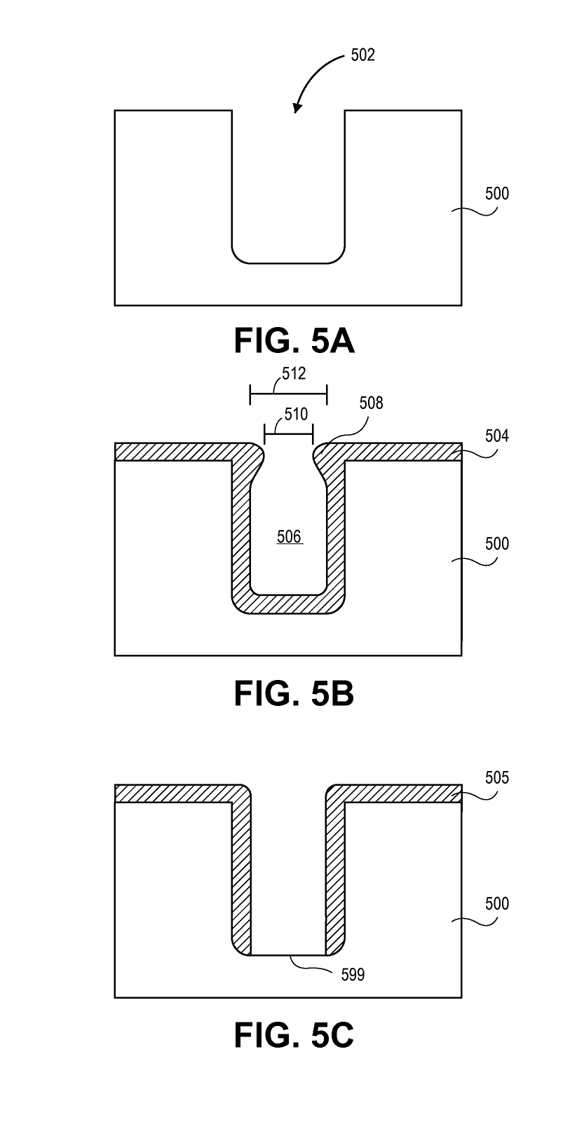

In another aspect of the present invention, the portion of a dielectric layer at the bottom of a deep trench is removed with a relatively high bias etch process to enable formation of desired features of the deep trench, such as formation of contacts absent a dielectric cap at the bottom of a deep trench. For example, FIG. 4 is a Flowchart 400 representing operations in a method of filling a deep trench in a substrate, in accordance with an embodiment of the present invention. FIGS. 5A-5C illustrate cross-sectional views representing operations in a method of filling a deep trench in a substrate, in accordance with an embodiment of the present invention.

Referring to operation 402 of Flowchart 400 and corresponding FIG. 5A, a method of filling a deep trench in a substrate includes providing a substrate 500 with a deep trench 502 formed therein.

Substrate 500 may be composed of a material suitable to withstand a fabrication process and upon which semiconductor processing layers may suitably reside. In accordance with an embodiment of the present invention, substrate 500 is composed of a group IV-based material such as, but not limited to, crystalline silicon, germanium or silicon/germanium. In a specific embodiment, providing substrate 500 includes providing a monocrystalline silicon substrate. In a particular embodiment, the monocrystalline silicon substrate is doped with impurity atoms. In another embodiment, substrate 500 is composed of a III-V material.

Deep trench 502 may be formed by a process suitable to form a deep trench having approximately the same dimensions, e.g. width, at the top of the trench as the bottom of the trench. In accordance with an embodiment of the present invention, deep trench 502 is formed by first forming a patterning film formed above substrate 500 and then etching substrate 500. The patterning film may be composed of a material suitable for deposition and patterning on a substrate. In an embodiment, the patterning film is composed of a layer of photo-resist and is suitable to withstand a deep substrate etch. The photo-resist layer may be composed of a material suitable for use in a lithographic process. In an embodiment, the photo-resist layer is exposed to a light source and subsequently developed. In one embodiment, the portions of the photo-resist layer to be exposed to the light source will be removed upon developing the photo-resist layer, e.g., the photo-resist layer is composed of a positive photo-resist material. In a specific embodiment, the photo-resist layer is composed of a positive photo-resist material such as, but not limited to, a 248 nm resist, a 193 nm resist, a 157 nm resist, an extreme ultra-violet (EUV) resist and a phenolic resin matrix with a diazonaphthoquinone sensitizer. In another embodiment, the portions of the photo-resist layer to be exposed to the light source will be retained upon developing the photo-resist layer, e.g., the photo-resist layer is composed of a negative photo-resist material. In a specific embodiment, the photo-resist layer is composed of a negative photo-resist material such as, but not limited to, poly-cis-isoprene and poly-vinyl-cinnamate. In an embodiment, the patterning film is composed of an I-line or G-line photo-resist material layer. In an embodiment, upon patterning the patterning film, substrate 500 is etched, e.g. by a plasma etch, in the regions of substrate 500 exposed by the pattern of the patterning film.

Referring to operation 404 of Flowchart 400 and corresponding FIG. 5B, a method of filling a deep trench in a substrate includes forming a dielectric layer 504 conformal with substrate 500 and deep trench 502 to provide a partially filled trench 506. In accordance with an embodiment of the present invention, forming dielectric layer 504 conformal with substrate 500 and deep trench 502 includes forming a pair of shoulders 508 at the top portion of deep trench 502, as depicted in FIG. 5B. In an embodiment, the spacing 510 between the pair of shoulders 508 is less than the width 512 of partially filled trench 506, e.g., less than the width between the sidewalls of dielectric layer 504 lower down in deep trench 502. In one embodiment, the pair of shoulders 508 results from characteristics inherent in the deposition of dielectric layer 504.

Dielectric layer 504 may be a material layer suitable for use as an insulating layer. In accordance with an embodiment of the present invention, the insulating layer is composed of a material such as, but not limited to, silicon oxide, silicon dioxide, silicon nitride, silicon oxy-nitride or a high-k dielectric layer. In a particular embodiment, forming dielectric layer 504 includes forming a layer consisting essentially of silicon dioxide. In an embodiment, dielectric layer 304 has a thickness approximately in the range of sub-100 nanometer-3 microns.

Referring to operation 406 of Flowchart 400 and corresponding FIG. 5C, a method of filling a deep trench in a substrate includes, with the entire portion of dielectric layer 504 conformal with deep trench 502 exposed, removing all of dielectric layer 504 at the bottom of deep trench 502 with a relatively high bias plasma etch process to form modified dielectric layer 505 and to expose a portion 599 of substrate 500. In accordance with an embodiment of the present invention, forming dielectric layer 504 conformal with substrate 500 and deep trench 502 includes forming the pair of shoulders 508 at the top portion of the deep trench, and removing all of dielectric layer 504 at the bottom of deep trench 502 further includes removing at least a portion of the pair of shoulders 508, as depicted in FIG. 5C. In one embodiment, removing the portion of the pair of shoulders 508 includes removing the entirety of the pair of shoulders 508, as is also depicted in FIG. 5C.

The high bias etch process may be an etch process suitable to entirely remove the portion of dielectric layer 504 at the bottom of deep trench 502 without significantly etching other regions of dielectric layer 504, such as without etching portions of dielectric layer 504 at the top of deep trench 502. However, in an embodiment, as described above, shoulders 508 are formed during the formation of dielectric layer 504. In one embodiment, shoulders 508 allow some residual etching of the portions of dielectric layer 504 at the top of deep trench 502, during removal of the portion of dielectric layer 504 at the bottom of deep trench 502, without significant detrimental impact to the final structure. In an alternative embodiment, shoulders 508 are not formed during the formation of dielectric layer 504 and are therefore not present for removal during the etching of the portion of dielectric layer 504 at the bottom of deep trench 502. In another alternative embodiment, the trench width to shoulder size ratio is large and the impact of the shoulders on the process is minimal. In another alternative embodiment, the trench width to dielectric layer 504 thickness ratio is large and the impact of the shoulders on the process is minimal.

In accordance with an embodiment of the present invention, removing the portion of dielectric layer 504 at the bottom of deep trench 502 with the relatively high bias plasma etch process includes applying a bias approximately in the range of 100-1000 Watts. In one embodiment, removing the portion of dielectric layer 504 at the bottom of deep trench 502 with the relatively high bias plasma etch process includes applying a bias approximately in the range of 300-500 Watts. In a specific embodiment, removing the portion of dielectric layer 504 at the bottom of deep trench 502 with the relatively high bias plasma etch process includes using a gaseous composition such as, but not limited to, helium or argon carrier gas approximately in the range of 0-400 sccm, along with a gas such as, but not limited to, SF₆ gas approximately in the range of 0-500 sccm, C₄F₈ gas approximately in the range of 0-500 sccm, CHF₃ gas approximately in the range of 0-500 sccm, CF₄ gas approximately in the range of 0-500 sccm, or O₂ gas approximately in the range of 0-100 sccm, the gaseous composition having a pressure approximately in the range of 10-200 mTorr, and the gaseous composition having a source power applied thereto approximately in the range of 1000-5000 Watts.

Although not depicted, the method of filling a deep trench in a substrate may also include forming a barrier layer and a seed layer on modified dielectric layer 505 and in deep trench 502 to form a partially filled trench. In accordance with an embodiment of the present invention, the barrier layer and the seed layer are formed at the bottom of the deep trench, where the portion of dielectric layer 504 has been removed.

The barrier layer may be composed of a material suitable to inhibit electro-migration within metal interconnects, to prevent oxidation of the metal interconnects, or to provide a surface for nucleation in a damascene process. In accordance with an embodiment of the present invention, the barrier layer is composed of a material such as, but not limited to, tantalum, titanium, tantalum nitride, titanium nitride or a combination thereof. In an embodiment, the thickness of the barrier layer is approximately in the range of 5-15 nanometers.

The seed layer may be composed of a material suitable to provide a surface for nucleation in a damascene process. In accordance with an embodiment of the present invention, the seed layer is composed of a material such as, but not limited to, copper or a copper/aluminum alloy.

Although also not depicted, the method of filling a deep trench in a substrate may also include forming a metal fill layer on the seed layer and in the partially filled trench to form an essentially or completely filled trench. In accordance with an embodiment of the present invention, the metal fill layer is composed of a material such as, but not limited to, copper, silver, aluminum or an alloy thereof. In an embodiment, modified dielectric layer 505, the barrier layer, the seed layer, and the metal fill layer essentially fill the deep trench. In a specific embodiment, modified dielectric layer 505, the barrier layer, the seed layer, and the metal fill layer essentially fill the deep trench.

In another aspect of the present invention, a repeated etch/substrate sidewall deposition cycle process may preliminarily be included for trench formation in a process wherein the portion of a dielectric layer at the bottom of a deep trench is removed with a relatively high bias etch process. In such an approach, a repeated etch/substrate sidewall deposition cycle process is applied, wherein a material layer is iteratively formed on the sidewalls of the deep trench throughout its formation. This approach may lead to the formation of scalloped features on the sidewalls of a deep trench, as described below. FIGS. 6A-6C illustrate cross-sectional views representing operations in a method of filling a deep trench in a substrate, in accordance with an embodiment of the present invention.

Referring to FIG. 6A, a method of filling a deep trench in a substrate includes providing a substrate 600 with a deep trench 602 formed therein. In accordance with an embodiment of the present invention, deep trench 602 has scalloped features 603 along its sidewalls, as depicted in FIG. 6A. Substrate 600 may be composed of a material such as the materials described above in association with substrate 500. Deep trench 502 may be formed by a process such as the processes described above in association with deep trench 502.

Referring to FIG. 6B, a method of filling a deep trench in a substrate includes forming a dielectric layer 604 conformal with substrate 600 and deep trench 602 with scalloped sidewall features 603 to provide a partially filled trench 606. In accordance with an embodiment of the present invention, forming dielectric layer 604 conformal with substrate 600 and deep trench 602 includes forming a pair of shoulders 608 at the top portion of deep trench 602, as depicted in FIG. 6B. In an embodiment, the spacing 610 between the pair of shoulders 608 is less than the width 612 of partially filled trench 606, e.g., less than the width between the sidewalls of dielectric layer 604 lower down in deep trench 602. In one embodiment, the pair of shoulders 608 results from characteristics inherent in the deposition of dielectric layer 604. Dielectric layer 604 may be a material layer such as the material layers described above in association with dielectric layer 504.

Referring to FIG. 6C, a method of filling a deep trench in a substrate includes, with the entire portion of dielectric layer 604 conformal with deep trench 602 exposed, removing all of dielectric layer 604 at the bottom of deep trench 602 with a relatively high bias plasma etch process to form modified dielectric layer 605 and to expose a portion 699 of substrate 600. In accordance with an embodiment of the present invention, forming dielectric layer 604 conformal with substrate 600 and deep trench 602 includes forming the pair of shoulders 608 at the top portion of the deep trench, and removing all of dielectric layer 604 at the bottom of deep trench 602 further includes removing at least a portion of the pair of shoulders 608, as depicted in FIG. 6C. In one embodiment, removing the portion of the pair of shoulders 608 includes removing the entirety of the pair of shoulders 608, as is also depicted in FIG. 6C.

The high bias etch process may be an etch process suitable to entirely remove the portion of dielectric layer 604 at the bottom of deep trench 602 without significantly etching other regions of dielectric layer 604, such as without etching portions of dielectric layer 604 at the top of deep trench 602. However, in an embodiment, as described above, shoulders 608 are formed during the formation of dielectric layer 604. In one embodiment, shoulders 608 allow some residual etching of the portions of dielectric layer 604 at the top of deep trench 602, during removal of the portion of dielectric layer 604 at the bottom of deep trench 602, without significant detrimental impact to the final structure. In an alternative embodiment, shoulders 608 are not formed during the formation of dielectric layer 604 and are therefore not present for removal during the etching of the portion of dielectric layer 604 at the bottom of deep trench 602.

In accordance with an embodiment of the present invention, removing the portion of dielectric layer 604 at the bottom of deep trench 602 with the relatively high bias plasma etch process includes applying a bias approximately in the range of 100-1000 Watts. In one embodiment, removing the portion of dielectric layer 604 at the bottom of deep trench 602 with the relatively high bias plasma etch process includes applying a bias approximately in the range of 300-500 Watts. In a specific embodiment, removing the portion of dielectric layer 604 at the bottom of deep trench 602 with the relatively high bias plasma etch process includes using a gaseous composition such as, but not limited to, helium or argon carrier gas approximately in the range of 0-400 sccm, along with a gas such as, but not limited to, SF₆ gas approximately in the range of 0-500 sccm, C₄F₈ gas approximately in the range of 0-500 sccm, CHF₃ gas approximately in the range of 0-500 sccm, CF₄ gas approximately in the range of 0-500 sccm, or O₂ gas approximately in the range of 0-100 sccm, the gaseous composition having a pressure approximately in the range of 10-200 mTorr, and the gaseous composition having a source power applied thereto approximately in the range of 1000-5000 Watts.

Although not depicted, the method of filling a deep trench in a substrate may also include forming a barrier layer and a seed layer on modified dielectric layer 605 and in deep trench 602 to form a partially filled trench. In accordance with an embodiment of the present invention, the barrier layer and the seed layer are formed at the bottom of the deep trench, where the portion of dielectric layer 604 has been removed. The barrier layer may be composed of a material such as the materials described in association with the barrier layer discussed above following the FIG. 5C description. The seed layer may be composed of a material such as the materials described in association with the seed layer discussed above following the FIG. 5C description.

Although also not depicted, the method of filling a deep trench in a substrate may also include forming a metal fill layer on the seed layer and in the partially filled trench to form an essentially or completely filled trench. In accordance with an embodiment of the present invention, the metal fill layer is composed of a material such as, but not limited to, copper, silver, aluminum or an alloy thereof. In an embodiment, modified dielectric layer 605, the barrier layer, the seed layer, and the metal fill layer essentially fill the deep trench. In a specific embodiment, modified dielectric layer 605, the barrier layer, the seed layer, and the metal fill layer essentially fill the deep trench.

Thus, methods of filling deep trenches in substrates have been disclosed. In accordance with an embodiment of the present invention, a method includes providing a substrate with a deep trench formed therein. The method also includes forming a dielectric layer conformal with the substrate and the deep trench. The method also includes, with the entire portion of the dielectric layer conformal with the deep trench exposed, removing at least a portion, but not all, of the dielectric layer at the top of the deep trench with a relatively low bias plasma etch process. In one embodiment, forming the dielectric layer conformal with the substrate and the deep trench includes forming a pair of shoulders at the top portion of the deep trench, and removing the portion of the dielectric layer at the top of the deep trench includes removing at least a portion of the pair of shoulders. In another embodiment, the method further includes, subsequent to removing the portion of the dielectric layer, forming a barrier layer conformal with the dielectric layer and the deep trench. A seed layer is then formed conformal with the barrier layer and the deep trench. A metal fill layer is then formed conformal with the seed layer and the deep trench. The dielectric layer, the barrier layer, the seed layer, and the metal fill layer essentially or completely fill the deep trench.

What is claimed is:

1. A method of filling a deep trench in a substrate, the method comprising:
providing a substrate with a deep trench formed therein;
forming a dielectric layer conformal with the substrate and the deep trench; and, with the entire portion of the dielectric layer conformal with the deep trench exposed,
removing at least a portion, but not all, of the dielectric layer at the top of the deep trench with a relatively low bias plasma etch process.

2. The method of claim 1, wherein forming the dielectric layer conformal with the substrate and the deep trench comprises forming a pair of shoulders at the top portion of the deep trench, and wherein removing the portion of the dielectric layer at the top of the deep trench comprises removing at least a portion of the pair of shoulders.

3. The method of claim 2, wherein removing the portion of the pair of shoulders comprises removing the entirety of the pair of shoulders.

4. The method of claim 1, wherein removing the portion of the dielectric layer with the relatively low bias plasma etch process comprises applying a bias approximately in the range of 0-200 Watts.

5. The method of claim 4, wherein removing the portion of the dielectric layer with the relatively low bias plasma etch process comprises applying a bias approximately in the range of 0-100 Watts.

6. The method of claim 5, wherein removing the portion of the dielectric layer with the relatively low bias plasma etch process comprises using a gaseous composition comprising helium or argon carrier gas approximately in the range of 0-400 sccm, along with a gas selected from the group consisting of SF₆ gas approximately in the range of 0-500 sccm, C₄F₈ gas approximately in the range of 0-500 sccm, CHF₃ gas approximately in the range of 0-500 sccm, CF₄ gas approximately in the range of 0-500 sccm, and O₂ gas approximately in the range of 0-100 sccm, the gaseous composition having a pressure approximately in the range of 10-200 mTorr, and the gaseous composition having a source power applied thereto approximately in the range of 1000-5000 Watts.

7. The method of claim 1, further comprising:
subsequent to removing the portion of the dielectric layer, forming a barrier layer conformal with the dielectric layer and the deep trench;
forming a seed layer conformal with the barrier layer and the deep trench; and
forming a metal fill layer conformal with the seed layer and the deep trench, wherein the dielectric layer, the barrier layer, the seed layer, and the metal fill layer essentially fill the deep trench.

8. The method of claim 7, wherein the dielectric layer, the barrier layer, the seed layer, and the metal fill layer completely fill the deep trench.

9. The method of claim 1, wherein forming the dielectric layer comprises forming a layer consisting essentially of silicon dioxide.

10. The method of claim 1, wherein providing the substrate comprises providing a monocrystalline silicon substrate.

11. A method of filling a deep trench in a substrate, the method comprising:
providing a substrate with a deep trench formed therein;
forming a dielectric layer conformal with the substrate and the deep trench; and, with the entire portion of the dielectric layer conformal with the deep trench exposed,
removing all of the dielectric layer at the bottom of the deep trench with a relatively high bias plasma etch process.

12. The method of claim 11, wherein forming the dielectric layer conformal with the substrate and the deep trench comprises forming a pair of shoulders at the top portion of the deep trench, and wherein removing all of the dielectric layer at the bottom of the deep trench further comprises removing at least a portion of the pair of shoulders.

13. The method of claim 12, wherein removing the portion of the pair of shoulders comprises removing the entirety of the pair of shoulders.

14. The method of claim 11, wherein removing all of the dielectric layer at the bottom of the deep trench with the relatively high bias plasma etch process comprises applying a bias approximately in the range of 100-1000 Watts.

15. The method of claim 14, wherein removing all of the dielectric layer at the bottom of the deep trench with the relatively high bias plasma etch process comprises applying a bias approximately in the range of 300-500 Watts.

16. The method of claim 15, wherein removing all of the dielectric layer at the bottom of the deep trench with the relatively high bias plasma etch process comprises using a gaseous composition comprising helium or argon carrier gas approximately in the range of 0-400 sccm, along with a gas selected from the group consisting of SF₆ gas approximately in the range of 0-500 sccm, C₄F₈ gas approximately in the range of 0-500 sccm, CHF₃ gas approximately in the range of 0-500 sccm, CF₄ gas approximately in the range of 0-500 sccm, and O₂ gas approximately in the range of 0-100 sccm, the gaseous composition having a pressure approximately in the range of 10-200 mTorr, and the gaseous composition having a source power applied thereto approximately in the range of 1000-5000 Watts.

17. The method of claim 11, further comprising:
subsequent to removing all of the dielectric layer at the bottom of the deep trench, forming a barrier layer conformal with the dielectric layer and the deep trench;
forming a seed layer conformal with the barrier layer and the deep trench; and
forming a metal fill layer conformal with the seed layer and the deep trench, wherein the dielectric layer, the barrier layer, the seed layer, and the metal fill layer essentially fill the deep trench.

18. The method of claim 17, wherein the dielectric layer, the barrier layer, the seed layer, and the metal fill layer completely fill the deep trench.

19. The method of claim 11, wherein forming the dielectric layer comprises forming a layer consisting essentially of silicon dioxide.

20. The method of claim 11, wherein providing the substrate comprises providing a monocrystalline silicon substrate.
